(19) United States
(12) Patent Application Publication
(10) Pub. No.: US 2017/0033266 A1
(43) Pub. Date: Feb. 2, 2017

(54) SUBSTRATE FOR LIGHT EMITTING DEVICE, LIGHT EMITTING DEVICE, AND METHOD FOR MANUFACTURING SUBSTRATE FOR LIGHT EMITTING DEVICE

(71) Applicant: Sharp Kabushiki Kaisha, Osaka-shi (JP)

(72) Inventors: Masahiro KONISHI, Osaka-shi (JP); Shin ITOH, Osaka-shi (JP); Hiroyuki NOKUBO, Osaka-shi (JP); Ippei YAMAGUCHI, Osaka-shi (JP)

(21) Appl. No.: 15/102,300

(22) PCT Filed: Nov. 5, 2014
(86) PCT No.: PCT/JP2014/079353

§ 371 Date: Jun. 7, 2016

(30) Foreign Application Priority Data
Dec. 18, 2013 (JP) 2013-261698

(51) Int. Cl. H01L 33/46; H01L 33/64; H01L 33/54; H01L 33/62; H01L 33/56

(52) U.S. Cl. CPC H01L 33/46; H01L 33/62; H01L 33/56; H01L 33/54; H01L 33/642

(57) ABSTRACT

There is provided a substrate excellent in high reflectance, high heat dissipation, withstand voltage property, and thermal and light stability. A substrate (5) includes an aluminum base (10), a reflective layer (17) which is formed between the aluminum base (10) and an electrode pattern (20) for electrical connection with a light emitting element to contain ceramic and reflects light from the light emitting element, and an intermediate layer (16) containing resin and having high thermal conductibility which is formed to reinforce withstand voltage performance of the reflective layer (17).

### TECHNICAL FIELD

The present invention relates to a substrate for a light emitting device including a base made of a metal material and an insulating layer which is formed between the base and an electrode pattern for electrical connection with a light emitting element to contain ceramic and reflects light from the light emitting element, a light emitting device using the substrate for a light emitting device, and a method for manufacturing the substrate for a light emitting device. The present invention relates particularly to a substrate for a light emitting device suitably provided in a light emitting device, a light emitting device using the substrate for a light emitting device, and a method for manufacturing the substrate for a light emitting device.

### BACKGROUND ART

Properties that a substrate used in a light emitting device is required to basically have include high reflectance, high heat dissipation, a withstand voltage, and long-term reliability. A substrate for a light emitting device used for high-intensity illumination, in particular, is required to have a high withstand voltage property.

Conventionally, a ceramic substrate, a substrate including an organic resist layer as an insulating layer on a metal base, or the like has been known as a substrate for a light emitting device. The configurations of a ceramic substrate and a substrate using a metal base will be described below.

### (Ceramic Substrate)

For example, a ceramic substrate is fabricated by forming an electrode pattern on a plate-like ceramic base. Increasing brightness by arranging a large number of light emitting elements on a substrate has been pursued in keeping with the trend toward higher-output light emitting devices. As a result, ceramic substrates have been growing in size every year.

More specifically, to implement provision of a common LED light emitting device used with input power of 30 W by, for example, arranging blue LED elements measuring about or around 650 μm by 650 μm on one substrate classified as a medium-sized one, about 100 blue LED elements are necessary. An example of a ceramic substrate having about 100 blue LED elements arranged thereon is one having a horizontal size of 20 mm by 20 mm or more and a thickness of about 1 mm.

To implement provision of a brighter LED light emitting device with input power of 100 W or more, a larger-sized ceramic substrate, on which 400 or more blue LED elements can be mounted at one stroke and which has a horizontal size of at least 40 mm by 40 mm or more, is needed as a result of technology development based on the above-described increase in size of ceramic substrates.

Despite attempts to implement commercially based provision of an upsized ceramic substrate in accordance with the above-described demand for ceramic substrate upsizing, commercially based provision has been difficult due to the three problems of the strength, the manufacturing precision, and the manufacturing cost of a ceramic substrate.

A ceramic material is basically pottery, and an upsized ceramic substrate suffers from a strength problem. If a ceramic substrate is thickened to overcome the problem, a new problem occurs. The new problem is that the material cost of the ceramic substrate increases at the same time as an increase in thermal resistance (a reduction in heat dissipation). Additionally, if a ceramic substrate is upsized, not only the outside dimensions of the ceramic substrate but also the dimensions of an electrode pattern to be formed on the ceramic substrate are likely to have errors. As a result, the manufacturing yield of ceramic substrates is likely to decrease, and the manufacturing cost of ceramic substrates is likely to increase.

### (Substrate Using Metal Base)

For the purpose of, for example, overcoming the above-described problems with a ceramic substrate, a metal base having high thermal conductibility may be used as a substrate used in a high-output light emitting device. In order to mount a light emitting element on the metal base, an insulating layer needs to be provided on the metal base for formation of an electrode pattern to be connected to the light emitting element.

Examples of a material which is conventionally used for an insulating layer in a substrate for a high-output light emitting device include an organic resist. An insulating layer may be formed using a ceramic-based paint. To improve light use efficiency in the substrate for a high-output light emitting device, the insulating layer needs to have high light reflectivity.

However, if the organic resist conventionally used as the insulating layer is used in the substrate for a high-output light emitting device, sufficient thermal conductibility, thermal stability, and light stability are not obtained, and a withstand voltage property necessary for the substrate for a high-output light emitting device is not obtained. Additionally, although light leaking out toward a metal base via the insulating layer needs to be reflected to improve the light use efficiency, the conventional configuration using the organic resist as the insulating layer is unable to achieve sufficient light reflectivity.

In contrast, in the case of a substrate for a high-output light emitting device in which a light reflective layer and insulating layer is formed on a surface of a metal base using a ceramic-based paint, provision of a substrate for a high-output light emitting device having good reflectance, thermal stability, and light stability can be implemented.

### CITATION LIST

### Patent Literature

PTL 1: Japanese Unexamined Patent Application Publication No. 59-149958 (laid-open on Aug. 28, 1984)

PTL 2: Japanese Unexamined Patent Application Publication No. 2012-102007 (laid-open on May 31, 2012)

PTL 3: Japanese Unexamined Patent Application Publication No. 2012-69749 (laid-open on Apr. 5, 2012)

PTL 4: Japanese Unexamined Patent Application Publication No. 2006-332382 (laid-open on Dec. 7, 2006)

### SUMMARY OF INVENTION

### Technical Problem

The substrate for a light emitting device, in which the light reflective layer and insulating layer is formed on the surface of the metal base using the ceramic-based paint, however, suffers from a problem. The problem is that the substrate is excellent in reflectance, thermal stability, and light stability but is low in withstand voltage property. For example, if an attempt is made to implement provision of a bright light emitting device for LED illumination with input power of 100 W or more using the substrate for a light emitting device, a high withstand voltage property necessary for a substrate for a light emitting device for high-intensity illumination purpose cannot be secured, unlike the above-described case of a ceramic substrate.

This is due to the following circumstances. In a high-intensity type illumination apparatus needing brightness, it is common to series-connect light emitting elements and cause the light emitting elements to emit light at a high voltage. In terms of short circuit prevention and safety, a withstand voltage property of, for example, 4 to 5 kV or more is needed in the illumination apparatus for the entire illumination apparatus. An equivalent withstand voltage property is often needed for a substrate for a light emitting device.

In the case of a ceramic substrate, an insulating layer is thick, and a withstand voltage property commensurate with the high-intensity type illumination apparatus is easily achieved. In contrast, in the case of the substrate for a light emitting device with the light reflective layer and insulating layer formed on the surface of the metal base using the ceramic-based paint, formation of the insulating layer is difficult. It is thus difficult to stably reproduce a withstand voltage property.

Examples of a ceramic-based paint used on a low-melting metal, such as aluminum, include one using a glass binder.

Use of the sol-gel process allows synthesis of a vitreous film at a temperature much lower than the melting temperature of glass without passage through a molten state. That is, firing at a low temperature, such as 200° C. to 500° C., allows formation of a ceramic layer or, to be exact, a mixed layer of ceramic and a vitreous substance with particles of ceramic covered with the vitreous substance. However, a vitreous substance appearing in a gelled state after drying a sol-like glass raw material forms a porous film. Although most of pores in the film disappear after sintering, pores cannot be completely closed even after the sintering if the film is thin. The mixed layer of ceramic and the vitreous substance may be inferior in withstand voltage property.

For this reason, if an attempt is made to stably secure high withstand voltage performance required by increasing the thickness of the light reflective layer and insulating layer, thermal stability increases, and heat dissipation decreases. If an attempt is made to form the light reflective layer and insulating layer that is a thick film by the sol-gel process, a crack is likely to appear in the film, and the withstand voltage property decreases.

Examples of a method for synthesizing the ceramic layer coated with the vitreous substance using a method other than the sol-gel process include use of a mixture of particles of ceramic and particles of low-melting glass. Particles of low-melting glass are temporarily melted and then cured to form a glass layer containing particles of ceramic. Even a low-melting glass needs a temperature of about 800° C. to 900° C., and a general low-melting metal, such as aluminum, cannot withstand the process.

As has been described above, a conventional substrate for a light emitting device using a metal base suffers from a problem. The problem is that a substrate low in thermal resistance and excellent in heat dissipation and excellent in reflectance and withstand voltage property does not exist in a form appropriate for mass production.

The present invention has been made in consideration of the above-described conventional problems, and has as its object to provide a substrate for a light emitting device having high reflectance, high heat dissipation, a withstand voltage property, and long-term reliability including thermal and light stability and excellent in mass productivity, a light emitting device using the substrate for a light emitting device, and a method for manufacturing the substrate for a light emitting device.

### Solution to Problem

In order to solve the above-described problems, a substrate for a light emitting device according to one aspect of the present invention includes a base made of a metal material, a first insulating layer which is formed between the base and an electrode pattern for electrical connection with a light emitting element to contain ceramic and reflects light from the light emitting element, and a second insulating layer containing resin and having high thermal conductibility which is formed to reinforce withstand voltage performance of the first insulating layer.

### Advantageous Effects of Invention

The one aspect of the present invention produces the effect of providing a substrate for a light emitting device having high reflectance, high heat dissipation, a withstand voltage property, and long-term reliability including thermal and light stability and excellent in mass productivity.

### BRIEF DESCRIPTION OF DRAWINGS

FIG. 1(a) is a plan view of a substrate according to a first embodiment of the present invention, FIG. 1(b) is a cross-sectional view of the substrate, and FIG. 1(c) is an enlarged view of a cross section of the substrate.

FIGS. 2(a) to 2(d) are schematic views for explaining a manufacturing process of the substrate according to the first embodiment of the present invention.

FIG. 3(a) is a plan view of a substrate according to a second embodiment of the present invention, FIG. 3(b) is a cross-sectional view of the substrate, and FIG. 3(c) is an enlarged view of a cross section of the substrate.

FIGS. 4(a) to 4(d) are schematic views for explaining a manufacturing process of the substrate according to the second embodiment of the present invention.

FIG. 5(a) is a plan view of a light emitting device according to a third embodiment of the present invention, and FIG. 5(b) is a cross-sectional view of the light emitting device.

FIG. 6 is a bird's-eye view of the light emitting device put on a heat sink.

FIG. 7(a) is a bird's-eye view of an illumination apparatus, to which the light emitting device according to the third embodiment of the present invention is applied, and FIG. 7(b) is a cross-sectional view of the illumination apparatus.

### DESCRIPTION OF EMBODIMENTS

Embodiments of the present invention will be described below in detail.

### First Embodiment

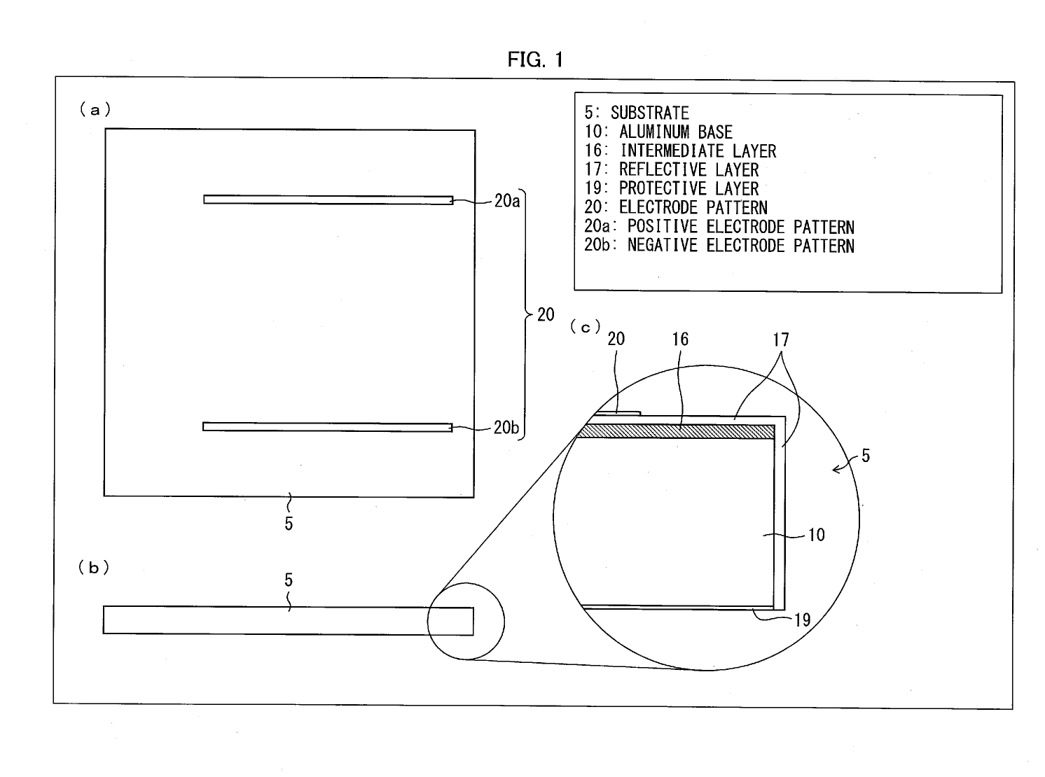

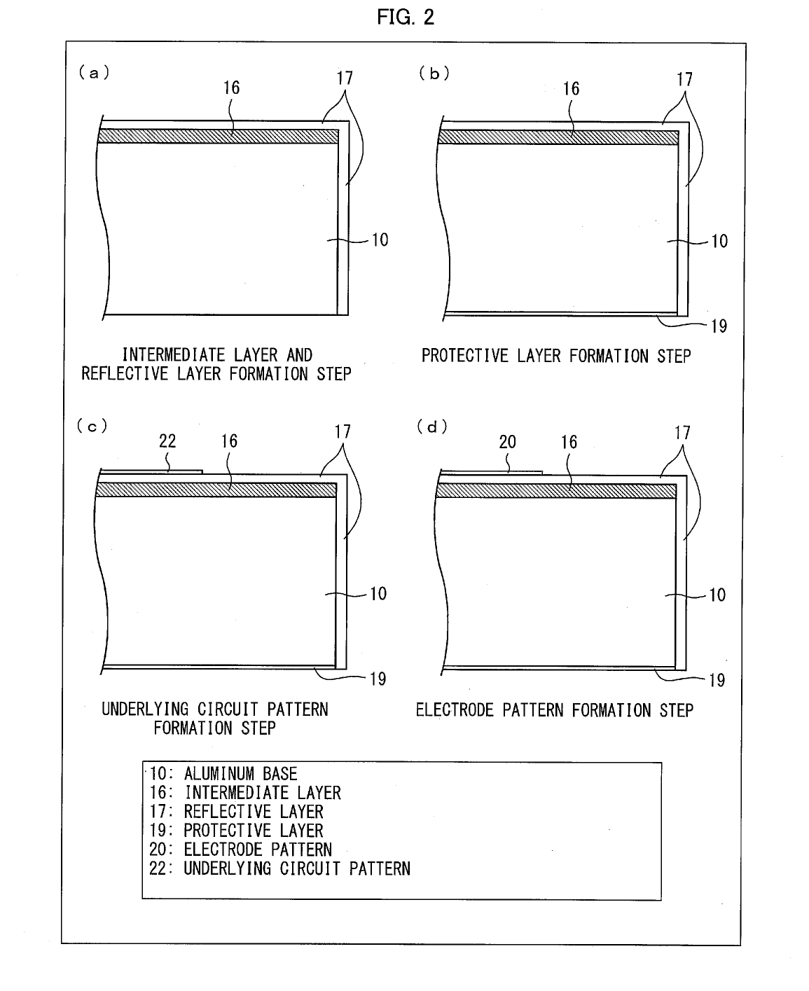

A first embodiment will be described with reference to FIGS. 1 and 2 as follows.

### (Structure of Substrate According to First Embodiment)

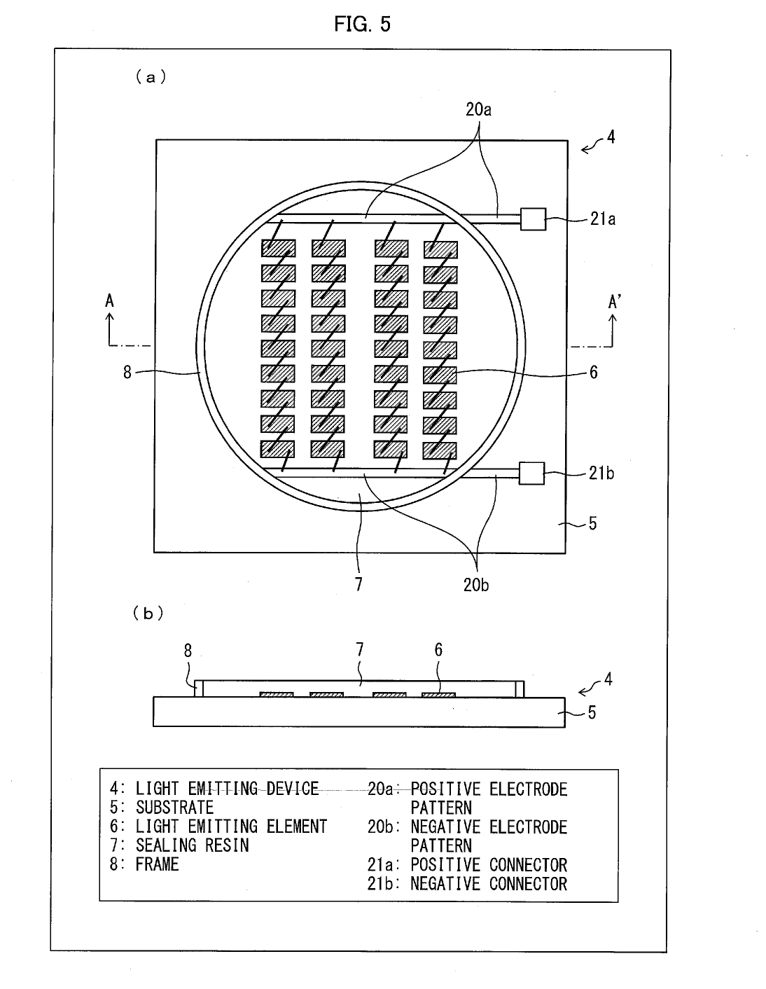

FIG. 1(a) is a plan view of a substrate (a substrate for a light emitting device) 5 according to a first embodiment of the present invention, FIG. 1(b) is a cross-sectional view of the substrate, and FIG. 1(c) is an enlarged view of a cross section of the substrate. The substrate 5 is used in a light emitting device 4 (FIG. 5) having light emitting elements 6 (FIG. 5) arranged thereon. An example of the light emitting device 4 is shown in FIG. 5. As is true with any of the drawings, the dimensions, the shapes, the numbers, and the like of a substrate, light emitting elements, and a light emitting device need not be equal to those of an actual substrate, actual light emitting elements, and an actual light emitting device. The light emitting device 4 using the substrate 5 will be described in a third embodiment.

As shown in FIG. 1(c), in the substrate 5, an intermediate layer (a second insulating layer) 16 is formed on a surface of an aluminum base (a base) 10. A reflective layer (a first insulating layer) 17 is formed so as to cover the intermediate layer 16 and end faces of the aluminum base 10. Electrode patterns 20 are formed on a surface opposite to a surface on the intermediate layer 16 side of the reflective layer 17. The electrode patterns 20 include a positive electrode pattern 20a and a negative electrode pattern 20b. The positive electrode pattern 20a and the negative electrode pattern 20b are each composed of an underlying circuit pattern (not shown) made of a conductive layer and plating covering the circuit pattern. The positive electrode pattern 20a and the negative electrode pattern 20b are pieces of wiring for electrical connection with the light emitting elements 6 (FIG. 5) arranged on the substrate 5. A protective layer (an alumite layer) 19 is formed so as to cover a surface opposite to the surface on the intermediate layer 16 side of the aluminum base 10.

The reflective layer 17 is formed between the aluminum base 10 and the electrode patterns 20, to which the light emitting elements 6 are to be electrically connected, to contain ceramic and reflects light from the light emitting element 6. The intermediate layer 16 contains resin and has high thermal conductibility, and reinforces the withstand voltage performance of the reflective layer 17. The thickness of the intermediate layer 16 is not less than 50 μm and not more than 150 μm.

The intermediate layer 16 and the reflective layer 17 are both insulating layers. The reflective layer 17 is set to have a thickness just enough to secure a light reflecting function, and a deficiency in withstand voltage performance of the reflective layer 17 is compensated for by a resin layer constituting the intermediate layer 16. Depending on a ceramic material to be mixed and the amount of the ceramic material, desired reflectance is achieved if the reflective layer 17 has a thickness approximately not less than 10 μm and not more than 100 μm. A thickness corresponding to a withstand voltage property of the intermediate layer 16 is preferably not less than 50 μm and not more than 150 μm, depending on ceramic and resin materials used for the intermediate layer 16 and the amounts of the materials to be compounded. For example, if the intermediate layer 16 has a thickness of 100 μm, the intermediate layer 16 alone can secure a withstand voltage property of at least 1.5 kV to 3 kV or more. If the thickness of the intermediate layer 16 is 150 μm, the intermediate layer 16 alone can secure a withstand voltage property of at least 2.3 kV to 4.5 kV. Eventually, the thickness of the intermediate layer 16 may be determined such that a withstand voltage which is the sum of the withstand voltage property of an insulating layer used as the reflective layer 17 and the withstand voltage property of an insulating layer used as the intermediate layer 16 is a desired withstand voltage. The reflective layer 17 and the intermediate layer 16 are preferably configured such that the total withstand voltage is about 4 kV to 5 kV.

The above-described formation of the electrode patterns 20 on an insulating layer including the intermediate layer 16 and the reflective layer 17 formed on the aluminum base 10 has allowed implementation of provision of a substrate for a light emitting device having high reflectance, high heat dissipation, a high withstand voltage property, and long-term reliability including thermal and light stability and suitable for high-intensity illumination.

For example, an aluminum plate 50 mm long, 50 mm wide, and 3 mmt high can be used as the aluminum base 10. Advantages of aluminum include light weight, excellence in workability, and high thermal conductivity. The aluminum base 10 may contain a component other than aluminum in an amount not to prevent anodic oxidation for formation of the protective layer 19.

In the present embodiment, the intermediate layer 16 that is an insulator containing resin and having high thermal conductibility intervenes between the reflective layer 17 and the aluminum base 10 to stably impart high withstand voltage characteristics and high heat dissipation to the substrate 5.

Resin is generally known to have low thermal conductivity. As for resin, of which the intermediate layer 16 is formed, provision of a resin layer having high thermal conductivity and excellent in electrical insulation is implemented by mixing particles of a ceramic having high thermal conductivity into a resin binder and curing the mixture. Epoxy resin is used here as the resin, of which the intermediate layer 16 is formed, and alumina (Al₂O₃) is used for particles of the above-described ceramic.

Besides alumina, aluminum nitride and silicon nitride are preferable for particles of the ceramic used in the intermediate layer 16 because the substances are good both in thermal conductivity and withstand voltage performance. Silicon carbide has high thermal conductivity, and zirconia and titanium oxide have high withstand voltage performance. For this reason, silicon carbide, zirconia, and titanium oxide may be properly used for particles of the ceramic used in the intermediate layer 16, depending on the purpose and use.

Particles of the ceramic here are not limited to a metal oxide and refer to ceramics in a broad sense, such as aluminum nitride, silicon nitride, and silicon carbide, that is, inorganic solid materials in general. Among the inorganic solid materials, any substance may be used for particles of the ceramic used in the intermediate layer 16 as long as the substance is a stable substance excellent in thermal stability and thermal conductibility and is a substance excellent in withstand voltage property.

As the resin binder used in the intermediate layer 16, a resin binder having a high withstand voltage property and high thermal stability is preferable. Besides epoxy resins as described above, polyimide resins, silicone resins, and fluororesins, typified by polytetrafluoroethylene (PTFE) and perfluoroalkoxy (PFA), are preferable as the resin binder used in the intermediate layer 16.

Particles of the ceramic are mixed into any of these resin binders, and drying and sintering and the like are performed, thereby forming the intermediate layer 16 made of the resin that has both high thermal conductivity and high insulation. The intermediate layer 16 may be formed by curing the resin binder after heating and melting the resin binder on the aluminum base 10 and joining the resin binder to the aluminum base 10 or may be formed by joining the resin formed in advance into a sheet to the aluminum base 10.

Note that a particle of the ceramic used in the intermediate layer 16 is desirably higher in thermal conductivity than a particle of a ceramic used in the reflective layer 17. As will be described later, particles of zirconia are used as particles of the ceramic in the reflective layer 17 in the present embodiment. In contrast to particles of zirconia in the reflective layer 17, alumina is used for particles of the ceramic in the intermediate layer 16. Since the thermal conductivity of alumina is higher than that of a particle of zirconia, it is possible to make the thermal conductivity of the intermediate layer 16 higher than that of the reflective layer 17 while maintaining a high withstand voltage.

A particle of a ceramic higher in thermal conductivity than a particle of the ceramic used in the reflective layer 17 is preferably used in the intermediate layer 16. The thermal conductivity of a particle of the ceramic of the intermediate layer 16 need not be higher than that of a particle of the ceramic of the reflective layer 17 as long as the thermal conductivity of the intermediate layer 16 is higher than that of the reflective layer 17. A particle of any ceramic may be used.

The reflective layer 17 is made of an insulating material which reflects light from the light emitting element 6 (FIG. 5). In the present embodiment, the reflective layer 17 is formed of an insulating layer containing particles of the ceramic. A particle of the ceramic has a high withstand voltage property and contributes to preventing the aluminum base 10 and the electrode patterns 20 from being short-circuited. The thickness of the reflective layer 17 is desirably, for example, about 50 μm to 100 μm in view of the reflectance of the substrate 5.

The protective layer 19 is an anodized aluminum coating (alumite). The protective layer 19 functions as a layer which prevents oxidation corrosion of the aluminum base 10 after completion of the substrate 5. Additionally, the protective layer 19 functions as a protective layer which protects the base 10 from a plating solution at the time of the plating process needed to form the electrode patterns 20 and, at the same time, prevents plating from being excessively precipitated, in a manufacturing process of the substrate 5.

### (Method for Manufacturing Substrate 5 According to First Embodiment)

FIGS. 2(a) to 2(d) are schematic views for explaining the manufacturing process of the substrate 5 according to the first embodiment of the present invention. A method for manufacturing the substrate 5 according to the first embodiment will be described with reference to FIG. 2.

The intermediate layer 16 is first formed on the surface of the base 10 (an intermediate layer formation step). The reflective layer 17 is formed so as to cover the intermediate layer 16 and the end faces of the aluminum base 10 (a reflective layer formation step). The protective layer 19 is formed so as to cover the back surface of the base 10 (a protective layer formation step).

In the present embodiment, the insulating reflective layer 17 that reflects light is an insulating layer containing zirconia as a light reflective ceramic and is formed by sintering using a glass-based binder. Since resin is used in the intermediate layer 16, a firing temperature for the reflective layer formation step that is a step subsequent to the intermediate layer formation step cannot be raised to a high temperature. For this reason, in the reflective layer formation step, the reflective layer 17 is formed by applying sol, which can be fired at a relatively low temperature and is used to synthesize a vitreous substance by the sol-gel process, onto the intermediate layer 16 by screen printing using the sol as a binder for particles of zirconia and performing drying and firing at 200° C.

Leading examples of particles of the light reflective ceramic used in the reflective layer 17 include titanium oxide, alumina, and aluminum nitride besides zirconia.

Particles of the ceramic here are also not limited to a metal oxide and refer to ceramics in a broad sense including aluminum nitride, that is, inorganic solid materials in general. Among the inorganic solid materials, any substance may be used for particles of the light reflective ceramic of the reflective layer 17 as long as the substance is a stable substance excellent in thermal stability and thermal conductibility and is a substance excellent in light reflection and light scattering. For this reason, particles which absorb light are not appropriate as particles of the ceramic of the reflective layer 17. For example, silicon nitride, silicon carbide, or the like is generally black and is not appropriate for particles of the ceramic used in the reflective layer 17.

The insulating reflective layer 17 that reflects light is an insulating layer containing a light reflective ceramic, such as zirconia. The reflective layer 17 is formed as an insulating reflective layer containing particles of the ceramic at an outermost layer of the substrate 5 by mixing particles of the ceramic into a glass-based binder or a resin binder having light and thermal stability and curing the binder by drying, firing, or the like.

The glass-based binder is made of a sol-like substance from which glass is synthesized by sol-gel reaction. The resin binder is made of epoxy resin or silicone resin that is excellent in thermal and light stability and high in transparency. Since the glass-based binder is more excellent in thermal and light stability and is higher in thermal conductivity than the resin binder, use of the glass-based binder is more preferable.

The glass-based binder used for the sol-gel process has a relatively low firing temperature of 200° C. to 500° C. If an appropriate process temperature is selected, no damage is given to the intermediate layer 16 in the manufacturing process even with use of an insulating layer made of resin as the intermediate layer 16. If the resin binder is used, no damage is similarly given to the intermediate layer 16.

Epoxy resin is used as the resin for the intermediate layer 16. Some of epoxy resins having high thermal stability withstand up to about 250° C. Use of the sol-gel process allows formation of the insulating reflective layer 17 with particles of zirconia covered with a vitreous layer on the intermediate layer 16 made of epoxy resin.

Among fluororesins, silicone resins, and polyimide resins, there is one higher in thermal stability than epoxy resins. A polyimide resin, in particular, may exceed 500° C. For this reason, as a temperature for firing using the sol-gel process, an optimum temperature may be adopted on the basis of the thermal stability of a resin to be used.

Besides the sol-gel process, there is available the process of forming a vitreous layer by remelting particles of low-melting glass bound by an organic binder. However, a minimum of 800° C. to 900° C. is needed for the remelting. For this reason, the process of forming a vitreous layer by the remelting is unsuitable for the present embodiment that uses resin as an insulator layer for the intermediate layer 16. Additionally, the temperature of 800° C. to 900° C. exceeds the melting point of 660° C. of aluminum used in the aluminum base 10. For this reason, to form the reflective layer 17 on the intermediate layer 16, synthesis of a vitreous substance by the sol-gel process is thus necessary.

Since glass is excellent in light stability and thermal stability, glass is most preferable as the material for the reflective layer 17. Instead of a vitreous substance, a resin excellent in thermal stability and light stability, such as silicone resin or epoxy resin, may be used as a binder for particles of ceramic to form the reflective layer 17. The resin is inferior in thermal stability and light stability to a vitreous substance but is lower in curing temperature than glass synthesis by the sol-gel process. This increases choices for a resin which can be used in the intermediate layer 16.

In actual manufacture, many pores formed in the anodized aluminum coating as the protective layer 19 are closed by performing sealing after alumite treatment. The sealing after the alumite treatment stabilizes the anodized aluminum coating forming the protective layer 19. For this reason, the protective layer 19 further ensures the durability and corrosion resistance of the aluminum base 10.

Formation of the protective layer 19 by alumite treatment is more desirably performed after formation of the reflective layer 17. As described above, in the step of forming the reflective layer 17, the reflective layer 17 is formed by applying a ceramic paint containing particles of ceramic onto the intermediate layer 16 and then synthesizing glass by the sol-gel process. A firing temperature at this time is 200° C. to 500° C.

Especially if firing is performed at a raised temperature of 250° C. or more, a crack (fissure) appears in the protective layer 19, and the function of the protective layer 19 as a protective film for a substrate for a light emitting device decreases. Additionally, with earlier formation of the reflective layer 17, the reflective layer 17 containing particles of ceramic serves as a mask for the alumite treatment in the step of forming the protective layer 19. Thus, only a portion on the aluminum base 10, where an aluminum-based material is exposed without the reflective layer 17, is covered by the protective layer 19.

With the intermediate layer formation step, the reflective layer formation step, and the protective layer formation step described above, the substrate 5, in which the aluminum base 10 is covered by the intermediate layer 16, the reflective layer 17, and the protective layer 19, is manufactured. The electrode patterns 20 are formed on the reflective layer 17 in the manner below.

As shown in FIG. 2(c), circuit patterns are drawn by printing or the like using metal paste made of resin containing particles of metal as foundations of the electrode patterns 20 and are dried, thereby forming underlying circuit patterns 22 (an underlying circuit pattern formation step). As shown in FIG. 2(d), metal for an electrode is precipitated on the underlying circuit patterns by the plating process, thereby forming the electrode patterns 20 (an electrode pattern formation step).

The aluminum base 10 is already coated with the high-reflectance reflective layer 17 containing ceramic and the protective layer 19 that is an anodized coating. For this reason, a plating solution used for the plating process in the electrode pattern formation step allows metal for an electrode to be efficiently precipitated from the plating solution only to the underlying circuit patterns 22 without erosion of the aluminum base 10.

As can be seen from the foregoing, according to the first embodiment, the substrate 5 is obtained by forming the intermediate layer 16 made of resin between the aluminum base 10 and the reflective layer 17 and forming the electrode patterns 20 on an insulating layer composed of the intermediate layer 16 and the reflective layer 17 and is thus a substrate for a light emitting device which has high reflectance, high heat dissipation, a high withstand voltage property, and long-term reliability including thermal and light stability and is suitable for high-intensity illumination. Additionally, the first embodiment allows provision of such a substrate for a light emitting device in a form excellent in mass productivity.

### Second Embodiment

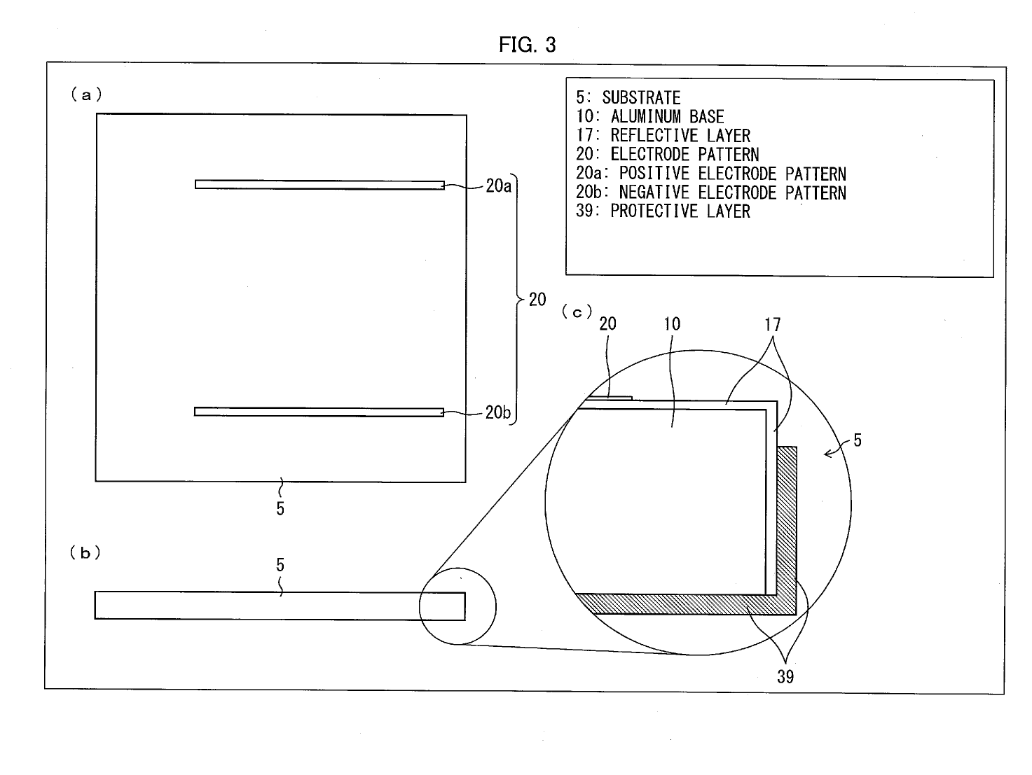

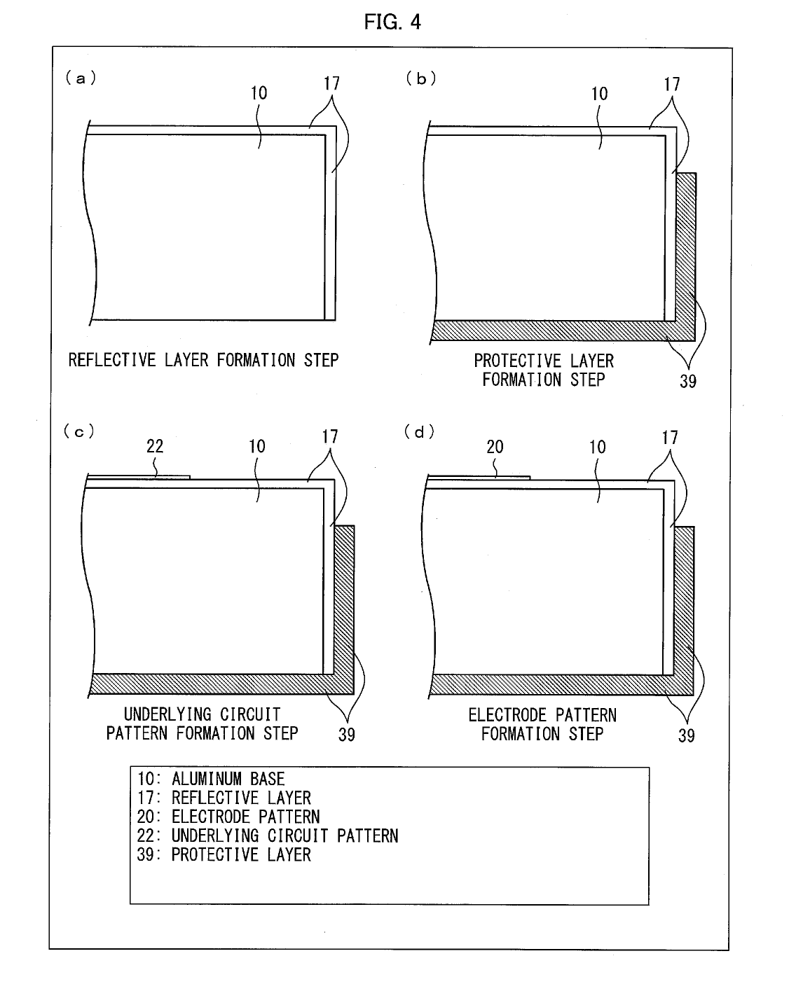

Another embodiment of the present invention will be described with reference to FIGS. 3 and 4 as follows. Note that members having the same functions as those of the members described in the above embodiment are denoted by the same reference characters for convenience of explanation and that a description thereof will be omitted.

FIG. 3(a) is a plan view of a substrate according to a second embodiment of the present invention, FIG. 3(b) is a cross-sectional view of the substrate, and FIG. 3(c) is an enlarged view of a cross section of the substrate. FIGS. 4(a) to 4(d) are schematic views for explaining a manufacturing process of the substrate according to the second embodiment of the present invention.

### (Structure of Substrate According to Second Embodiment)

A substrate (a substrate for a light emitting device) 5 includes an aluminum base (a base) 10. A reflective layer (a first insulating layer) 17 is formed so as to cover a surface and end faces of the aluminum base 10. A protective layer 39 is formed so as to cover a back surface of the aluminum base 10 and the reflective layer 17 formed on the end faces of the aluminum base 10. Electrode patterns 20 are formed on the reflective layer 17.

In the first embodiment, thermal conductible resin is inserted as the intermediate layer 16 between the aluminum base 10 and the reflective layer 17. The present invention, however, is not limited to this. A substance made of the material for the intermediate layer 16 according to the first embodiment described earlier may be arranged as the protective layer 39 on the back surface of the aluminum base 10. The same applies to a case where the material for the base 10 is copper.

In a structure in which the reflective layer 17 and the intermediate layer 16 are arranged immediately below light emitting elements 6 (FIG. 5), like the structure of the substrate 5 illustrated in the first embodiment, the thermal resistance of the reflective layer 17 and the intermediate layer 16 largely affect the thermal resistance of the entire substrate 5. If the need to increase the thickness of the intermediate layer 16 arises to achieve a desired withstand voltage, the thermal resistance may rise higher than expected. To avoid this, the intermediate layer 16 may be arranged on the back surface of the aluminum base 10 away from the light emitting elements 6 (FIG. 5) as a heat source. If the intermediate layer 16 lower in thermal conductivity than the base 10 is arranged at the position of the protective layer 39 away from the light emitting elements 6, the thermal resistance of the protective layer 39 can be reduced in spite of the same thermal conductivity. This is because heat diffuses in a horizontal direction parallel to a surface of the substrate 5 before the heat finishes passing through the protective layer 39.

As described above, the contribution ratio of the thermal resistance of the protective layer 39 to the thermal resistance of the entire substrate 5 can be made much lower than that of the thermal resistance of the intermediate layer 16 according to the first embodiment. For this reason, insulation can be enhanced by making the thickness of the protective layer 39 sufficiently larger than that of the protective layer 39 when used as the intermediate layer 16. Even if the thickness of the protective layer 39 is increased, the thermal resistance of the protective layer 39 only slightly affects the thermal resistance of the entire substrate 5. For this reason, the protective layer 39 has a high withstand voltage and can have thermal resistance reduced to low. As a guide, if the sum of the thicknesses of the reflective layer 17 and the intermediate layer 16 or the sum for the reflective layer 17 and the protective layer 39 exceeds 150 μm to 200 μm, the thermal resistance of a light emitting device per light emitting element is very high. If the configuration of the second embodiment is adopted instead of that of the first embodiment in this case, it is possible to reduce thermal resistance to low while enhancing insulation. The thickness of the reflective layer 17 is preferably not less than 10 μm and not more than 100 μm. The thickness of the protective layer 39 is preferably not less than 50 μm.

### (Method for Manufacturing Substrate According to Second Embodiment)

FIGS. 4(a) to 4(d) are schematic views for explaining a manufacturing process of the substrate according to the second embodiment of the present invention. A method for manufacturing the substrate 5 according to the second embodiment will be described with reference to FIG. 4.

As shown in FIG. 4(a), the reflective layer 17 is formed on the surface and the end faces of the base 10 (a reflection layer formation step). As shown in FIG. 4(b), the protective layer 39 is formed on the back surface of the base 10 and a surface of the reflective layer 17 corresponding to the end faces of the base 10 (a protective layer formation step). As shown in FIG. 4(c), circuit patterns are drawn by printing or the like using metal paste made of resin containing particles of metal as foundations of the electrode patterns 20 and are dried, thereby forming underlying circuit patterns 22 on the reflective layer 17 (an underlying circuit pattern formation step). As shown in FIG. 4(d), metal for an electrode is precipitated on the underlying circuit patterns by the plating process, thereby forming the electrode patterns 20 (an electrode pattern formation step).

The formation of the protective layer 39 offers a manufacturing advantage. Formation of the protective layer 39 made of resin is performed after formation of the reflective layer 17, and the firing temperature of the reflective layer 17 is not limited by the upper temperature limit of the protective layer 39. As described in the first embodiment, a temperature, at which a vitreous substance is fired using the sol-gel process, is 200° C. to 500° C. In the second embodiment, it is also possible to bond the protective layer 39 onto the back surface of the base 10 after forming the reflective layer 17 by performing firing at a high temperature of 500° C. for a short time. In the case of the intermediate layer 16 according to the first embodiment, the intermediate layer 16 needs to be formed prior to formation of the reflective layer 17, the process temperature of the reflective layer 17 is limited by the upper temperature limit of the intermediate layer 16. Additionally, in the first embodiment, firing of the reflective layer 17 does not cause deterioration of resin in the protective layer 39.

Whether insulation is provided mainly on an upper surface of the aluminum base 10 (for example, the intermediate layer 16 according to the first embodiment) or on a lower surface of the aluminum base 10 (for example, the protective layer 39 according to the second embodiment) depends on what an illumination apparatus is like, and cannot be determined only on the basis of thermal resistance and the degree of freedom of a method of manufacturing. Both a configuration with the intermediate layer 16 and a configuration with the protective layer 39 can be selected as the structure of a substrate for a light emitting device according to the present embodiment.

### Third Embodiment

The present embodiment will describe a light emitting device 4 which is fabricated using a substrate 5 illustrated in the first or second embodiment. FIGS. 5(a) and 5(b) show a plan view and a front cross-sectional view, respectively, of the light emitting device 4 according to the present embodiment. Note that the number of light emitting elements 6 has been expediently and greatly reduced in the drawings for the sake of simplicity.

The light emitting device 4 is a light emitting device of a chip on board (COB) type, in which a plurality of light emitting elements 6, such as an LED element or an EL element, are mounted on the substrate 5 described in either the first embodiment or the second embodiment.

A frame 8 which is provided around a rim of a sealing resin 7 to surround the plurality of light emitting elements 6 is provided on the substrate 5. The sealing resin 7 is charged into the frame 8 to seal the light emitting elements 6. The sealing resin 7 excites a phosphor with light emitted from the light emitting element 6 and contains the phosphor that convers the light into light having a different wavelength. With this configuration, the light emitting elements 6 give off plane emissions on a surface of the sealing resin 7.

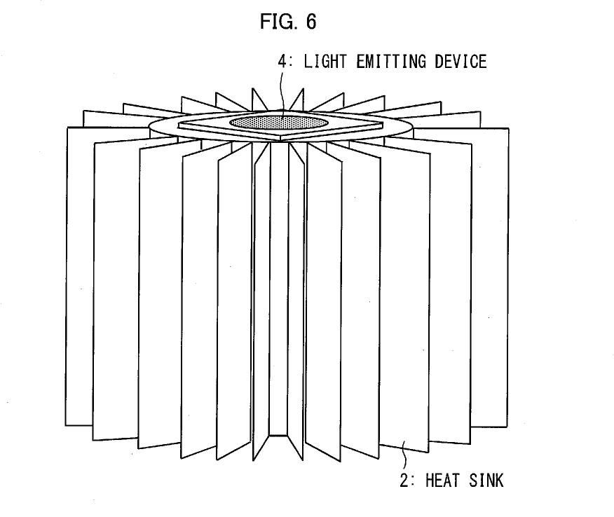

With integration of a large number of light emitting elements 6, 10 W, 50 W, 100 W, 100 W or more, or the like is used as power input to the light emitting device 4, and high-intensity emitted light is obtained. For example, to implement provision of the high-output light emitting device 4, in which the light emitting elements 6 of a medium size of about 500 μm by 800 μm are integrated on the substrate 5 and which has input power of about 100 W, as many as about 300 to 400 light emitting elements 6 need to be integrated. Since integration of a large number of light emitting elements 6 increases heat generated in the light emitting device 4, high heat dissipation may be secured by a heat sink 2 much larger in volume than the light emitting device 4, as shown in FIG. 6.

As the light emitting element 6, for example, a blue LED, a purple LED, an ultraviolet LED, or the like can be used. As a phosphor to be charged into the sealing resin 7, for example, a phosphor which emits light of any one of blue, green, yellow, orange, and red or a combination of arbitrary phosphors can be used. With the phosphors, light of a desired color can be emitted from the light emitting device 4. Note that a phosphor (phosphors) may be omitted from the sealing resin 7 and that the light emitting elements 6 of the three colors of blue, green, and red having different luminous wavelengths may be arranged on the substrate 5. Alternatively, two arbitrary colors may be used in combination or a single color may be used.

The light emitting elements 6 are connected to a positive electrode pattern 20a and a negative electrode pattern 20b. The positive electrode pattern 20a is connected to a positive connector 21a for connecting the light emitting elements 6 to external wiring or an external apparatus via the positive electrode pattern 20a. The negative electrode pattern 20b is connected to a negative connector 21b for connecting the light emitting elements 6 to external wiring or an external apparatus via the negative electrode pattern 20b. The positive connector 21a and the negative connector 21b may each be composed of a land, and the positive electrode pattern 20a and the negative electrode pattern 20b may each be connected to the external wiring or the external apparatus by soldering.

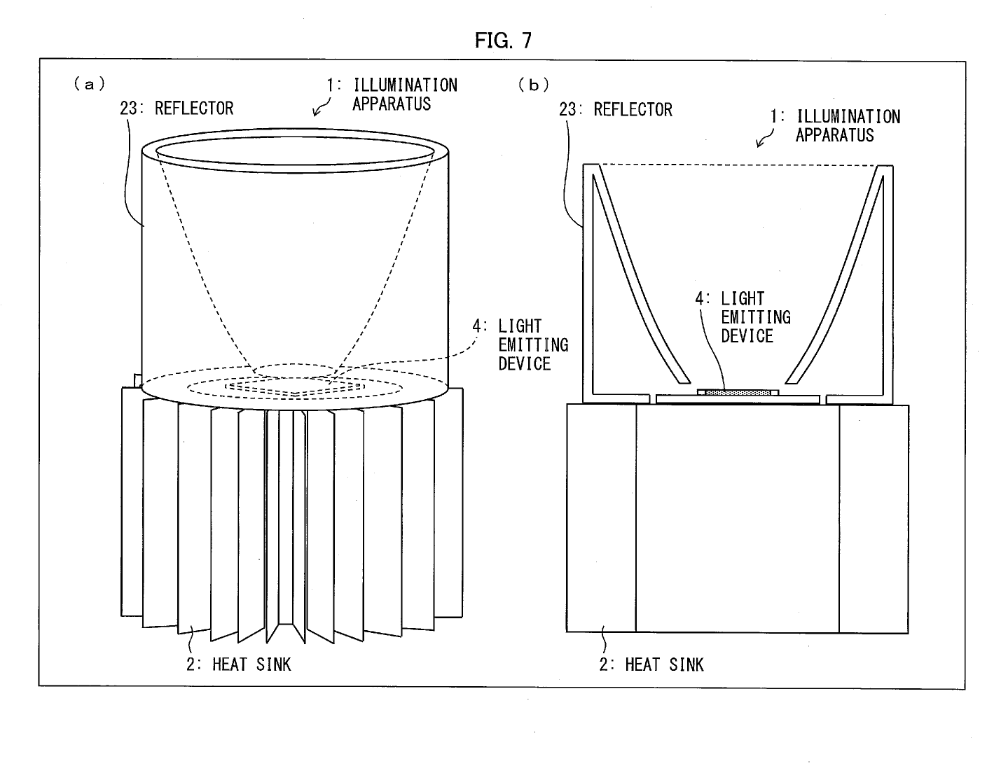

The light emitting device 4 can be applied to, for example, an illumination apparatus 1 as shown in FIG. 7. The illumination apparatus 1 includes the light emitting device 4, a heat sink 2 for dissipating heat generated from the light emitting device 4, and a reflector 23 which reflects light emitted from the light emitting device 4.

### SUMMARY

A substrate for a light emitting device according to a first aspect of the present invention includes a base (an aluminum base 10) made of a metal material, a first insulating layer (a reflective layer 17) which is formed between the base (the aluminum base 10) and an electrode pattern 20 for electrical connection with a light emitting element 6 to contain ceramic and reflects light from the light emitting element 6, and a second insulating layer (an intermediate layer 16 or a protective layer 39) containing resin and having high thermal conductibility which is formed to reinforce withstand voltage performance of the first insulating layer (the reflective layer 17).

According to the above-described configuration, the second insulating layer containing resin and having high thermal conductibility reinforces the withstand voltage performance of the first insulating layer. This leads to provision of a substrate for a light emitting device having an excellent withstand voltage property in addition to high reflectance, high heat dissipation, and long-term reliability including thermal and light stability.

According to a second aspect of the present invention, in the substrate for a light emitting device of the first aspect, the thermal conductivity of the second insulating layer may be higher than thermal conductivity of the first insulating layer.

According to the above-described configuration, the thermal conductivity of the second insulating layer can be made higher than that of the first insulating layer. This leads to provision of a substrate for a light emitting device which has high heat dissipation while maintaining a high withstand voltage property and high reflectance.

According to a third aspect of the present invention, in the substrate for a light emitting device of the first aspect, the base may include an aluminum material or a copper material.

According to the above-described configuration, a material which is light in weight, is excellent in workability, and is high in thermal conductivity can be used as a material for the base.

According to a fourth aspect of the present invention, in the substrate for a light emitting device, it is preferable that the base include an aluminum material, the first insulating layer coat part of the base, and the substrate further include an alumite layer (the protective layer 19) which coats a whole or part of the rest of the base.

According to the above-described configuration, the alumite layer allows prevention of corrosion due to oxidation of the base. The alumite layer also allows the substrate to be protected from erosion by a plating solution at a time of plating the electrode pattern.

According to a fifth aspect of the present invention, in the substrate for a light emitting device, the second insulating layer is preferably formed between the first insulating layer and the base.

According to the above-described configuration, the second insulating layer formed between the first insulating layer and the base allows reinforcement of the withstand voltage performance of the first insulating layer.

According to a sixth aspect of the present invention, in the substrate for a light emitting device, it is preferable that a thickness of the second insulating layer be not less than 50 μm and not more than 150 μm and a thickness of the first insulating layer be not less than 10 μm and not more than 100 μm.

According to the above-described configuration, the second insulating layer can suitably reinforce the withstand voltage performance of the first insulating layer, and the first insulating layer can suitably reflect light from the light emitting element.

According to a seventh aspect of the present invention, in the substrate for a light emitting device, the second insulating layer (the protective layer 39) is preferably formed on a surface opposite to a surface on the first insulating layer (the reflective layer 17) side of the base (the aluminum base 10).

According to the above-described configuration, the second insulating layer lower in thermal conductivity than the base is arranged at a position away from the light emitting element 6. Thermal resistance of the second insulating layer can thus be reduced even if the second insulating layer has an unchanged thickness and unchanged thermal conductivity. This is because heat diffuses in a horizontal direction parallel to a surface of the substrate for a light emitting device before completion of passage through the second insulating layer.

According to an eighth aspect of the present invention, in the substrate for a light emitting device, it is preferable that a thickness of the second insulating layer (the protective layer 39) be not less than 50 μm and a thickness of the first insulating layer (the reflective layer 17) be not less than 10 μm and not more than 100 μm.

According to the above-described configuration, heat diffuses in a horizontal direction parallel to a surface of the substrate for a light emitting device before completion of passage through the second insulating layer. This leads to a reduction in thermal resistance of the second insulating layer.

According to a ninth aspect of the present invention, in the substrate for a light emitting device, it is preferable that the second insulating layer contain at least one of epoxy resin, polyimide resin, silicone resin, and fluororesin and the fluororesin include at least one of PTFE resin and PFA resin.

According to the above-described configuration, the second insulating layer is excellent in thermal stability. This leads to easy formation of the first insulating layer after formation of the second insulating layer.

According to a 10th aspect of the present invention, in the substrate for a light emitting device, the resin in the second insulating layer is preferably has thermal conductivity enhanced by mixing particles of ceramic into a resin binder.

According to the above-described configuration, the thermal conductivity of the second insulating layer can be enhanced. This leads to easy dissipation of heat from the light emitting element through the second insulating layer.

According to an 11th aspect of the present invention, in the substrate for a light emitting device, the particles of the ceramic preferably contain at least one of aluminum nitride (AlN), alumina (Al₂O₃), silicon carbide (SiC), silicon nitride (Si₃N₄), zirconia (ZrO₂), and titanium oxide (TiO₂).

According to the above-described configuration, the material is excellent in withstand voltage performance. This leads to suitable reinforcement of the withstand voltage performance of the first insulating layer.

According to a 12th aspect of the present invention, in the substrate for a light emitting device, it is preferable that the first insulating layer be formed by covering particles of ceramic with a vitreous substance and the particles of the ceramic contain at least one of zirconia, titanium oxide, alumina, and aluminum nitride.

According to the above-described configuration, glass is excellent in light stability and thermal stability. Glass is thus preferable as a material for the reflective layer.

According to a 13th aspect of the present invention, in the substrate for a light emitting device, it is preferable that the particles of the ceramic in the second insulating layer contain at least one of aluminum nitride, alumina, silicon carbide, and silicon nitride, the first insulating layer contain resin having particles of ceramic, the particles of the ceramic contain at least one of zirconia and titanium oxide, and the resin in the first insulating layer be silicone resin, epoxy resin, or fluororesin.

A light emitting device according to a 14th aspect of the present invention includes a substrate for a light emitting device according to the present invention, the light emitting element, a land or a connector for connecting the light emitting element to external wiring or an external apparatus via the electrode pattern, a frame which is formed to surround the light emitting element, and a sealing resin, with which the light emitting element surrounded by the frame is sealed.

According to the above-described configuration, the same effects as those of the substrate for a light emitting device according to the first aspect of the present invention can be produced.

A method for manufacturing a substrate for a light emitting device according to a 15th aspect of the present invention is a method for manufacturing the substrate for a light emitting device according to the fifth aspect of the present invention, the method including forming the second insulating layer on the base, forming the first insulating layer on the second insulating layer, and forming the electrode pattern on the first insulating layer.

According to the above-described configuration, the same effects as those of the substrate for a light emitting device according to the fifth aspect of the present invention can be produced.

According to a 16th aspect of the present invention, in the method for manufacturing a substrate for a light emitting device, the second insulating layer is preferably formed by joining resin which is formed in advance into a sheet to the base. Alternatively, the second insulating layer is preferably formed by curing a resin to be cured which is formed in advance into a sheet using heat or light after bonding the resin to the base, and joining the resin to the base.

According to the above-described configuration, a resin layer having high thermal conductivity can be formed as the second insulating layer.

According to a 17th aspect of the present invention, in the method for manufacturing a substrate for a light emitting device, the second insulating layer is preferably formed by curing a resin binder on the base.

According to the above-described configuration, a resin layer having high thermal conductivity can be formed as the second insulating layer.

According to an 18th aspect of the present invention, in the method for manufacturing a substrate for a light emitting device, it is preferable that the second insulating layer contain PFA resin and the second insulating layer be formed by melting the PFA resin and then curing and joining the PFA resin to the base.

According to a 19th aspect of the present invention, in the method for manufacturing a substrate for a light emitting device, the first insulating layer is preferably formed using a resin binder. More preferably, a vitreous substance is formed on the first insulating layer through sol-gel reaction of a glass raw material.

According to a 20th aspect of the present invention, in the method for manufacturing a substrate for a light emitting device, the first insulating layer is preferably formed using a resin binder. More preferably, a vitreous substance is formed on the first insulating layer through sol-gel reaction of a glass raw material. It is preferable that the second insulating layer be formed by joining resin which is formed in advance into a sheet to the base, the second insulating layer be formed by curing resin to be cured which is formed in advance into a sheet using heat or light after bonding the resin to the base, and joining the resin to the base, the second insulating layer be formed by curing a resin binder on the base, or the second insulating layer contain PFA resin and be formed by melting the PFA resin and then curing and joining the PFA resin to the base.

A method for manufacturing a substrate for a light emitting device according to a 21st aspect of the present invention is a method for manufacturing the substrate for a light emitting device according to the seventh aspect, the method including forming the first insulating layer on the base, forming the second insulating layer on a surface opposite to a surface on the first insulating layer side of the base, and forming the electrode pattern on the first insulating layer.

According to the above-described configuration, the same effects as those of the substrate for a light emitting device according to the seventh aspect can be produced.

The present invention is not limited to the above-described embodiments, and various changes may be made within the scope of the claims. An embodiment obtained by appropriately combining technical means disclosed in different embodiments is also included in the technical scope of the present invention. Additionally, a new technical feature can be formed by combining technical means disclosed in the embodiments.

### INDUSTRIAL APPLICABILITY

A substrate for a light emitting device according to the present invention can be used as a substrate for various types of light emitting devices. A light emitting device according to the present invention can be used, in particular, as a high-intensity LED light emitting device. A method for manufacturing a substrate for a light emitting device according to the present invention allows a substrate for a light emitting device for a light emitting device excellent in withstand voltage property and heat dissipation to be manufactured by a method excellent in mass productivity.

### REFERENCE SIGNS LIST

1 illumination apparatus
2 heat sink
4 light emitting device
5 substrate (substrate for light emitting device)
6 light emitting element
7 sealing resin
8 frame
10 aluminum base (base)
16 intermediate layer (second insulating layer)
17 reflective layer (first insulating layer)
19 protective layer (aluminate layer)
20 electrode pattern
21a positive connector (connector)
21b negative connector (connector)
39 protective layer (second insulating layer)

1.-5. (canceled)

6. A substrate for a light emitting device, comprising:
a base made of a metal material;
a first insulating layer which is formed between the base and an electrode pattern for electrical connection with a light emitting element to contain ceramic and reflects light from the light emitting element; and
a second insulating layer containing resin and having high thermal conductibility which is formed to reinforce withstand voltage performance of the first insulating layer,
the second insulating layer being higher in thermal conductivity than the first insulating layer.

7. The substrate for a light emitting device according to claim 6, wherein the base includes an aluminum material or a copper material.

8. The substrate for a light emitting device according to claim 6, wherein
the base includes an aluminum material,
the first insulating layer coats a part of the base, and
the substrate further includes an alumite layer which coats a whole or a part of the rest of the base.

9. The substrate for a light emitting device according to claim 6, wherein the second insulating layer is formed between the first insulating layer and the base.

10. The substrate for a light emitting device according to claim 9, wherein
a thickness of the second insulating layer is not less than 50 μm and not more than 150 μm, and
a thickness of the first insulating layer is not less than 10 μm and not more than 100 μm.

11. The substrate for a light emitting device according to claim 6, wherein the second insulating layer is formed on a surface opposite to a surface on a first insulating layer side of the base.

12. The substrate for a light emitting device according to claim 11, wherein
a thickness of the second insulating layer is not less than 50 μm, and
a thickness of the first insulating layer is not less than 10 μm and not more than 100 μm.

13. The substrate for a light emitting device according to claim 6, wherein the second insulating layer is formed of a resin obtained by mixing particles of ceramic into a resin binder.

14. The substrate for a light emitting device according to claim 13, wherein the particles of the ceramic contain at least one of aluminum nitride, alumina, silicon carbide, silicon nitride, zirconia, and titanium oxide.

15. The substrate for a light emitting device according to claim 13, wherein
the resin binder contains at least one of epoxy resin, polyimide resin, silicone resin, and fluororesin, and
the fluororesin includes at least one of PTFE resin and PFA resin.

16. The substrate for a light emitting device according to claim 6, wherein
the first insulating layer is formed by covering particles of ceramic with a vitreous substance and the particles of the ceramic contain at least one of zirconia, titanium oxide, alumina, and aluminum nitride.

17. The substrate for a light emitting device according to claim 6, wherein
the first insulating layer is formed of a resin obtained by mixing particles of ceramic into a resin binder,
the particles of the ceramic contain at least one of zirconia, titanium oxide, alumina, and aluminum nitride, and
the resin binder contains at least one of epoxy resin, fluororesin, silicone resin, and polyimide resin.

18. A light emitting device comprising:
a substrate for a light emitting device according to claim 6;
the light emitting element;
a land or a connector for connecting the light emitting element to external wiring or an external apparatus via the electrode pattern;
a frame which is formed to surround the light emitting element; and
a sealing resin, with which the light emitting element surrounded by the frame is sealed.
